(19) United States
(12) Patent Application Publication
(10) Pub. No.: US 2026/0040988 A1
(43) Pub. Date: Feb. 5, 2026

(54) METHOD OF FABRICATING SEMICONDUCTOR PACKAGES TO MITIGATE VOIDS THEREIN

(71) Applicant: Micron Technology, Inc., Boise, ID (US)

(72) Inventors: Pei Sian Shao, Taichung City (TW); Kai-Wei Chao, Taichung City (TW); Chen Hua Yang, Taichung City (TW)

(21) Appl. No.: 19/255,367

(22) Filed: Jun. 30, 2025

Related U.S. Application Data
(60) Provisional application No. 63/677,208, filed on Jul. 30, 2024.

(51) Int. Cl. H01L 21/56; H01L 23/31

(52) U.S. Cl. CPC H01L 21/561; H01L 23/3107

(57) ABSTRACT

Methods for fabricating a semiconductor package and devices formed therefrom are disclosed herein. The method includes inserting a substrate with a chip-on-wafer (CoW) arrangement thereon into a chamber of a mold of a compression molding apparatus. The method also includes positioning a film over the CoW arrangement. The method further includes dispensing, after positioning the film over the CoW arrangement, a liquid-type molding compound into the chamber. The method further includes compressing the liquid-type molding compound and the film to form a molding underfill (MUF) to surround and encapsulate the CoW arrangement.

### CROSS-REFERENCE TO RELATED APPLICATION

This application claims the benefit under 35 U.S.C. § 119(e) of U.S. Provisional Patent Application Ser. No. 63/677,208, filed Jul. 30, 2024, the disclosure of which is hereby incorporated herein in its entirety by this reference.

### TECHNICAL FIELD

This disclosure relates generally to methods of fabricating semiconductor packages. More particularly, the present disclosure relates to mitigating voids formed within the semiconductor packages during the fabrication thereof.

### BACKGROUND

During the formation of semiconductor packages (e.g., encapsulated assemblies of stacked microelectronic devices, such as high-bandwidth memory (HBM)), voids may form within the molding underfill (MUF), such as at a center of the semiconductor package at the wafer level, during a compression molding process.

The void distribution may overlap with dispensing distribution of encapsulation molding compound (EMC). Trapped air in the bond line may be blocked by the EMC, preventing extraction thereof during vacuum process. The trapped gas (e.g., air, without limitation) may be pushed towards the package center and cause voids to form in the MUF.

### BRIEF DESCRIPTION OF THE DRAWINGS

FIG. 1 is a perspective schematic view of a semiconductor package;

FIG. 2 is a side schematic view of a mold of a compression molding apparatus for fabricating semiconductor packages;

FIG. 3 is a side schematic view of the mold of FIG. 2 in a compressed position;

FIG. 4 a side schematic view of a semiconductor package fabricated in accordance with embodiments of the disclosure; and

FIG. 5 is a flowchart of a method for fabricating a semiconductor package in accordance with embodiments of the disclosure.

### DETAILED DESCRIPTION

In various embodiments, a method for fabricating a semiconductor package includes utilizing a film (e.g., a non-conductive film (NCF) or thin film of sheet type molding compound, without limitation) with a liquid-type molding compound to form a molding underfill (MUF) around a chip-on-wafer (CoW) arrangement positioned on the substrate during a compression molding process. The presence of the film may reduce or prevent gas (e.g., air at the bond line) from trapping within the MUF during compression and formation thereof.

The illustrations presented herein are not actual views of any system, device, or structure, or any component thereof, but are merely idealized representations, which are employed to describe embodiments of the present invention.

As used herein, the singular forms following “a,” “an,” and “the” are intended to include the plural forms as well, unless the context clearly indicates otherwise.

As used herein, any relational term, such as “first,” “second,” “top,” “bottom,” “upper,” “lower,” “above,” “beneath,” “side,” “upward,” “downward,” etc., is used for clarity and convenience in understanding the disclosure and accompanying drawings, and does not connote or depend on any specific preference or order, except where the context clearly indicates otherwise. For example, these terms may refer to an orientation of elements of any system, device, or structure, when utilized in a conventional manner. Furthermore, these terms may refer to an orientation of elements of any system, device, or structure, as illustrated in the drawings.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

As used herein, “about” or “approximately” in reference to a numerical value for a particular parameter is inclusive of the numerical value and a degree of variance from the numerical value that one of ordinary skill in the art would understand is within acceptable tolerances for the particular parameter. For example, “about” or “approximately” in reference to a numerical value may include additional numerical values within a range of from 90.0 percent to 112.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein the term “film” means and includes a sheet of material residing on a structure, which may be continuous or discontinuous between portions of the material, and which may be conformal or non-conformal, unless otherwise indicated.

As used herein, the term “compound” means and includes a composite material including two or more materials having different properties (physical properties and/or chemical properties) than one another. Within the context of this disclosure, a compound is not limited to a chemical species including two or more elements chemically bonded to each other in a fixed ratio.

As used herein, the term “substrate” means and includes a base material or construction upon which additional materials are formed. The substrate may be a semiconductor substrate, a base semiconductor layer on a supporting structure, a metal electrode, or a semiconductor substrate having one or more materials, layers, structures, or regions formed thereon. The materials on the semiconductor substrate may include, but are not limited to, semiconductive materials, insulating materials, conductive materials, etc. The substrate may be a conventional silicon substrate or other bulk substrate comprising a layer of semiconductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped. In some embodiments, the substrate may comprise a printed circuit board, or an interposer.

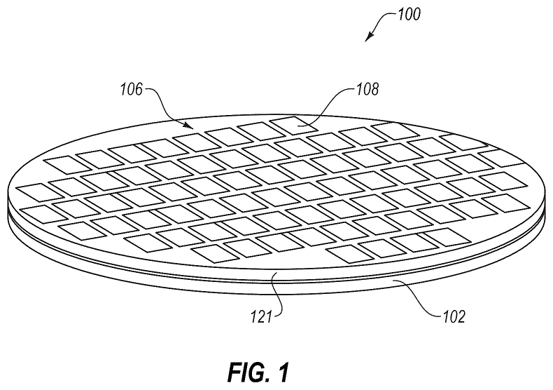

FIG. 1 is a perspective schematic view of a semiconductor package 100. The semiconductor package 100 includes a substrate 102 and a chip-on-wafer (CoW) arrangement 106 positioned on the substrate 102. The CoW arrangement 106 includes multiple die stacks 108. Each of the die stacks 108 includes multiple semiconductor die 110 in a vertically stacked relationship with one another. An individual semiconductor die 110 of an individual die stack 108, for example, comprise microelectronic device (e.g., a memory device). A lowest semiconductor die 110 of an individual die stack 108 is tacked to the substrate 102 at a respective semiconductor dice location. The substrate 102 may include conductive elements (e.g., conductive routing, conductive interconnects), through silicon via (TSV) structures, and other elements of microelectronic devices.

The semiconductor package 100 also includes a mold underfill (MUF) 112. The MUF 112 may substantially surround and encapsulate the CoW arrangement 106. In some embodiments, the MUF 112 is also located within spaces between vertically neighboring semiconductor die 110 within individual die stacks 108 of the CoW arrangement 106 (e.g., layered between semiconductor die 110 of an individual die stack 108 of the CoW arrangement 106, without limitation). The MUF 112 includes an encapsulation molding compound (EMC) that is compressed to surround the CoW arrangement 106.

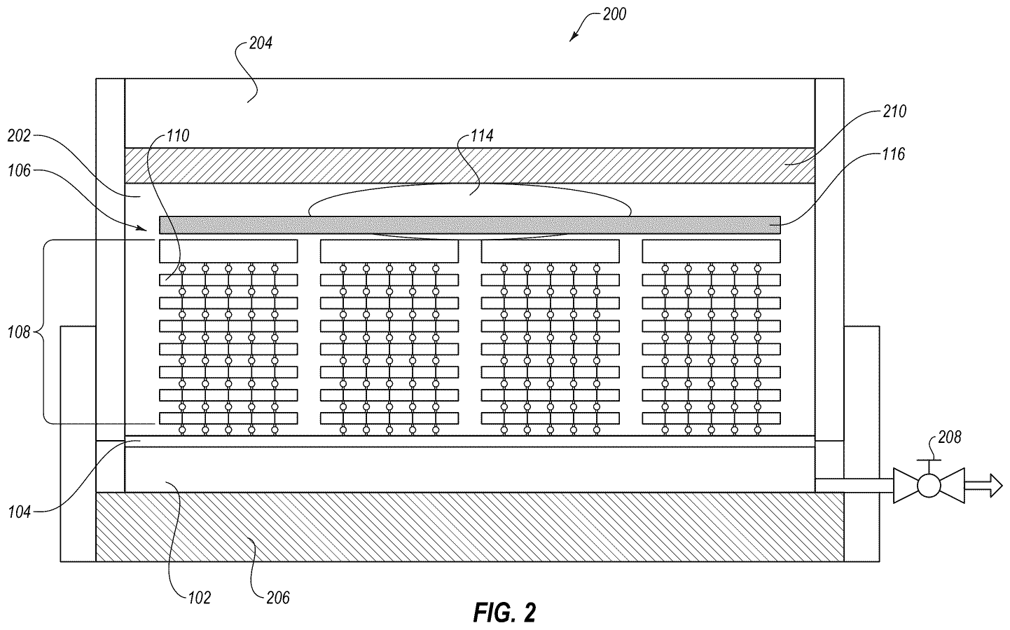

FIG. 2 is a side schematic view of a mold 200 of a compression molding apparatus for fabricating semiconductor packages. Referring to FIG. 2, the mold 200 may include an upper mold segment 204, a lower mold segment 206, and a vacuum valve 208. The upper mold segment 204 and the lower mold segment 206 are configured to be compressed towards one another to compress materials therebetween. The vacuum valve 208 is configured to allow gaseous material, such as air, to be drawn out of the chamber 202 defined by the upper mold segment 204 and the lower mold segment 206. The mold 200 may also include a release film 210 configured to facilitate removal of a formed semiconductor package 100 from the mold 200.

The substrate 102 with the CoW arrangement 106 thereon is positioned within the chamber 202 between the upper mold segment 204 and the lower mold segment 206.

A film 116 is positioned above the CoW arrangement 106, and a liquid-type of molding compound 114 (e.g., an EMC, without limitation, hereinafter referred to as molding compound 114) is dispensed into the chamber. In various embodiments, the film 116 is an NCF, a film of a sheet type molding compound, or a combination thereof. The NCF may be a thin, slow-cure, NCF.

The film 116 may be laminated on top of the CoW arrangement 106 prior to dispensing the molding compound 114. In various embodiments, the film 116 includes a thickness within a range of from about 5 microns (μm) to about 500 microns (μm). The film 116 may act as a blocker for the molding compound 114, which may prevent gas from trapping at the bond line during compression and vacuum of the molding compound 114. The film 116 may include epoxy resin, filler (e.g., silicon oxide, without limitation), hardener, polymeric material, and flux (e.g., solder fluxing by organic acid-based fluxes and reaction with oxirane of epoxy resins, without limitation).

The molding compound 114 may include epoxy resin, filler (e.g., silicon oxide, without limitation), hardener, release agent (e.g., wax, without limitation), pigment (e.g., carbon black, without limitation), and adhesives.

The release film 210 may be positioned below the upper mold segment 204 and above the CoW arrangement 106, the molding compound 114, and the film 116.

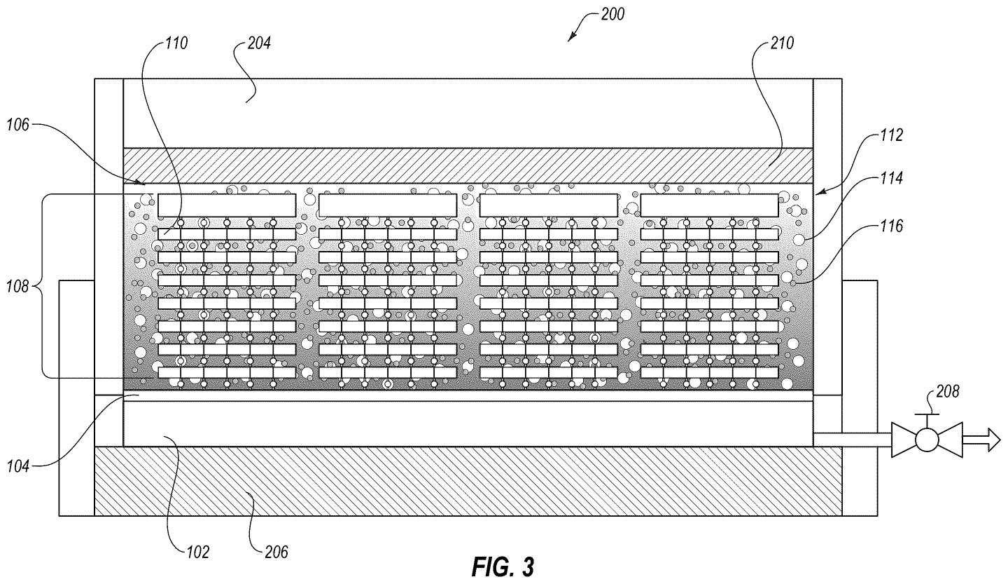

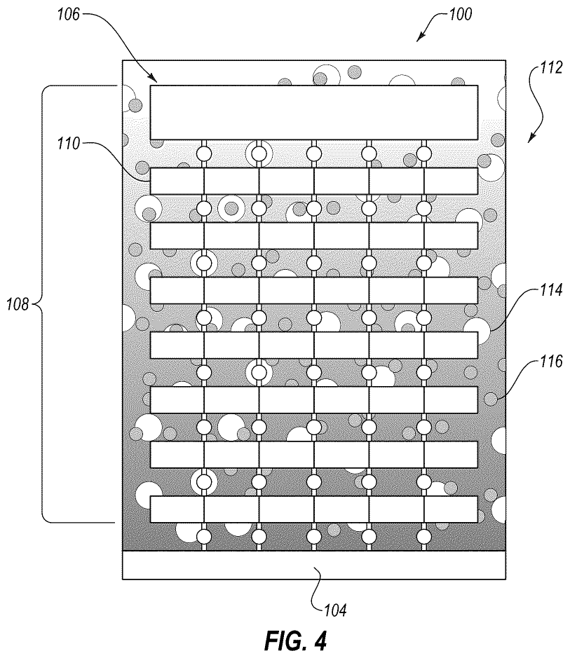

FIG. 3 is a side schematic view of the mold 200 of FIG. 2 in a compressed position. FIG. 4 is a side schematic view of a semiconductor package fabricated in accordance with embodiments of the disclosure. Referring to FIGS. 3 and 4, during a compression molding process, the molding compound 114 is compressed around the film 116, and the film 116 melts and mixes with the molding compound 114 to form the MUF 112 to substantially surround and encapsulate the die stacks 108 of the CoW arrangement 106. As shown in FIG. 3, in some embodiments the MUF 112 is also formed to at least partially fill spaces between vertically neighboring semiconductor die 110 within individual die stacks 108 of the CoW arrangement 106.

The gaseous material within the chamber 202 is drawn out via vacuum through the vacuum valve 208. The MUF 112 may be a heterogenous compound including material of the film 116 and the molding compound 114 or may be a substantially homogenous compound including material of the film 116 and the molding compound 114. The compositions of the film 116 and the molding compound 114 may be selected to facilitate desirable properties for the MUF 112.

By laminating a film 116 on top of the CoW arrangement 106 prior to dispensing the molding compound 114 within the chamber 202, voids formed within the MUF 112 may be significantly reduced or eliminated, while also reducing the cost and inaccuracy resulting from the use sheet type molding compounds. For example, unit sheet weight is fixed and cannot dynamically change with live package quantity, and storage is more difficult and requires more space than liquid-type.

Referring to FIG. 4, in various embodiments, the semiconductor package 100 includes a wafer 104, a CoW arrangement 106 including a die stack 108 (e.g., stacked microelectronic devices, without limitation), and a MUF 112. The wafer 104 may be formed from the substrate 102 by thinning or removing other portions of the substrate 102 therefrom. For example, the substrate 102 may be thinned from an initial thickness (e.g., within a range of from about 600 microns (μm) to about 700 microns (μm)) to a final, reduced, thickness (e.g., within a range of from about 30 microns (μm) to about 50 microns (μm)).

The MUF 112 comprises a compound formed from combined materials of the film 116 and the molding compound 114. As noted above, the compound may be a heterogenous compound of materials the film 116 and the molding compound 114 or may be substantially homogenous compound of materials the film 116 and the molding compound 114.

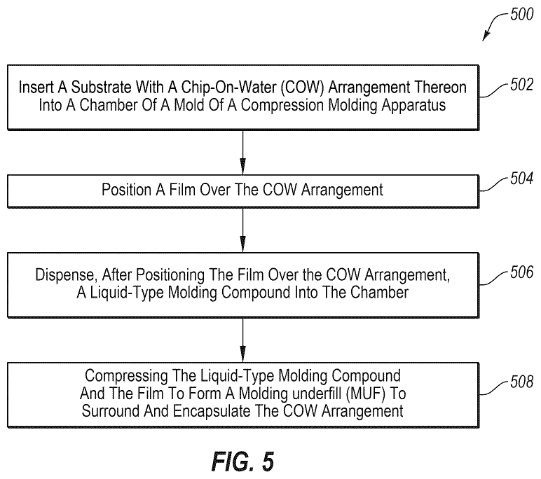

FIG. 5 is a flowchart of a method 500 for fabricating a semiconductor package in accordance with embodiments of the disclosure. The method 500 includes inserting a substrate with a CoW arrangement thereon into a chamber of a mold of a compression molding apparatus at act 502. Act 502 may include inserting the substrate with the CoW between an upper mold segment and a lower mold segment defining the chamber.

In various embodiments, the substrate may be positioned adjacent the lower mold segment with the CoW arrangement closer to the upper mold segment than the substrate. In other various embodiments, the substrate with the CoW arrangement thereon is inverted within the chamber, the substrate being secured to the upper mold segment. The substrate and the CoW arrangement may be the substrate 102 (FIG. 2) and the CoW arrangement 106 (FIG. 2), respectively, or similar structures known in the art.

The method 500 also includes positioning a film over the CoW arrangement at act 504. Act 504 may include laminating the film over the CoW arrangement (e.g., on an end of the CoW arrangement opposite the substrate). The film may be the film 116 (FIG. 2), or similar structure(s) known in the art. In various embodiments, the film is chosen from among an NCF and a film of a sheet type molding compound. In various embodiments, the film includes one or more of materials chosen from among a polymer and a flux.

The film may be laminated on the CoW arrangement opposite the substrate between an adjacent mold segment and the CoW arrangement (e.g., between the CoW arrangement and the upper mold segment in a standard orientation or between the CoW arrangement and the lower mold segment in an inverted orientation, without limitation). In various embodiments, the film is positioned over the CoW arrangement prior to insertion of the substrate with the CoW arrangement thereon into the chamber of the mold.

The method 500 further includes, dispensing, after positioning the film over the CoW arrangement, a liquid-type molding compound into the chamber at act 506. In various embodiments, the liquid-type molding compound is initially dispensed into the chamber between the film and the upper mold segment. The liquid-type molding compound may be the molding compound 114 (FIG. 3), or any other liquid molding compound known in the art for fabricating semiconductor packages.

The method 500 further includes compressing the liquid-type molding compound and the film to form a MUF to surround and encapsulate the CoW arrangement at act 508. During act 508, the film melts and mixes with the liquid-type molding compound. As a result, the MUF, formed to substantially surround and encapsulate die stacks of the CoW arrangement, comprises one of a heterogenous compound of the liquid-type molding compound and material of the film and a substantially homogenous compound of the liquid-type molding compound and material of the film. In various embodiments, a portion of the liquid-type molding compound is dispensed during act 508 to ensure a sufficient amount of the liquid-type molding compound is present during the compressing process.

The method 500 may further include vacuuming (e.g., applying negative pressure to) gaseous material present within the chamber therefrom during act 508. The vacuuming combined with the presence of the film during act 508 may reduce the amount of voids formed by gas trapped within the chamber during the compression molding process.

The method 500 may further include forming a wafer by thinning or removing portions of the substrate therefrom.

As the MUF is a compound of the liquid-type molding compound and material of the film, the use of method 500 to fabricate a semiconductor package may be determined by the detection of materials unique to films that may be used in the method 500. For example, polymers and fluxes unique to NFCs may be detectable in the MUF under inspection, such as via a microscope (e.g., a scanning electron microscope, without limitation). Other structural differences may also be detectable.

The semiconductor packages fabricated in accordance with embodiments of the disclosure may be used in various electronic systems (e.g., computers, computer hardware components, servers, networking hardware components, cellular telephones, digital cameras, personal digital assistants (PDAs), portable media players, Wi-Fi or cellular-enabled tablets, electronic books, navigations devices, or other systems that utilize semiconductor packages, without limitation).

In one illustrative embodiment, the present disclosure provides a method for fabricating a semiconductor package. The method includes inserting a substrate with a chip-on-wafer (CoW) arrangement thereon into a chamber of a mold of a compression molding apparatus. The method also includes positioning a film over the CoW arrangement. The method further includes dispensing, after positioning the film over the CoW arrangement, a liquid-type molding compound into the chamber. The method further includes compressing the liquid-type molding compound and the film to form a molding underfill (MUF) to surround and encapsulate the CoW arrangement.

In another illustrative embodiment, the present disclosure provides a semiconductor package including a wafer; a chip-on-wafer (CoW) arrangement on the wafer, and a molding underfill (MUF) around the CoW arrangement. The MUF includes a compound formed from a non-conductive film (NCF) and a molding compound.

In a further illustrative embodiment, the present disclosure provides a method for fabricating a semiconductor package. The method includes positioning a non-conductive film (NCF) over a chip-on-wafer (CoW) arrangement located on a substrate, the NCF positioned on an end of the CoW arrangement opposite the substrate. The method also includes dispensing, after positioning the film over the CoW arrangement, a liquid-type molding compound into a chamber of a mold of a compression molding apparatus while the CoW arrangement and substrate are positioned therein. The method further includes compressing the liquid-type molding compound and the NCF to form a molding underfill (MUF) around the CoW arrangement.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A method comprising:
inserting a substrate with a chip-on-wafer (CoW) arrangement thereon into a chamber of a mold of a compression molding apparatus;
positioning a film over the CoW arrangement;
dispensing, after positioning the film over the CoW arrangement, a liquid-type molding compound into the chamber; and
compressing the liquid-type molding compound and the film to form a molding underfill (MUF) to surround and encapsulate the CoW arrangement.

2. The method of claim 1, wherein the film is chosen from among a non-conductive film (NCF) and a film of a sheet-type molding compound.

3. The method of claim 2, wherein the NCF comprises a slow-cure NCF.

4. The method of claim 1, wherein positioning the film over the CoW arrangement includes laminating the film over the CoW arrangement on an end of the CoW arrangement opposite the substrate.

5. The method of claim 4, wherein the laminating the film over the CoW arrangement is performed prior to inserting the substrate with the CoW arrangement thereon into the chamber of the mold.

6. The method of claim 1, wherein the film comprises one or more materials chosen from among a polymer and a flux.

7. The method of claim 1, wherein the film is configured to melt and mix with the liquid molding compound during the compressing the liquid-type molding compound and the film to form the MUF around the CoW arrangement.

8. The method of claim 1, wherein the MUF, formed around the CoW arrangement, comprises one of a heterogenous compound and a homogenous compound of the liquid-type molding compound and the film.

9. The method of claim 1, wherein a portion of the liquid-type molding compound is dispensed during the compressing the liquid-type molding compound and the film to form the MUF around the CoW arrangement to ensure a sufficient amount of the liquid-type molding compound is present during the compressing process.

10. The method of claim 1, further comprising removing portions of the substrate therefrom to form a wafer.

11. A semiconductor package formed by the method of claim 1, the semiconductor package comprising:
a wafer formed from the substrate;
the CoW arrangement on the wafer; and
the MUF around the CoW arrangement, the MUF comprising one of a heterogenous compound and a substantially homogenous compound of the liquid-type molding compound and material of the film.

12. A semiconductor package comprising:
a wafer;
a chip-on-wafer (CoW) arrangement on the wafer; and
a molding underfill (MUF) around the CoW arrangement, the MUF comprising a compound formed from a non-conductive film (NCF) and a molding compound.

13. The semiconductor package of claim 12, wherein the MUF comprising the compound formed from the NCF and the molding compound is layered between die of an individual die stack of the CoW arrangement.

14. The semiconductor package of claim 12, wherein the NCF comprises one or more of materials chosen from among a polymer and a flux.

15. The semiconductor package of claim 12, wherein the MUF comprises one of:
a heterogenous compound of the molding compound and material of the film; and
a substantially homogenous compound of the molding compound and material of the film.

16. A method comprising:
positioning a non-conductive film (NCF) over a chip-on-wafer (CoW) arrangement located on a substrate, the NCF positioned on an end of the CoW arrangement opposite the substrate;
dispensing, after positioning the film over the CoW arrangement, a liquid-type molding compound into a chamber of a mold of a compression molding apparatus while the CoW arrangement and substrate are positioned therein; and
compressing the liquid-type molding compound and the NCF to form a molding underfill (MUF) around the CoW arrangement.

17. The method of claim 16, wherein the NCF comprises a slow-cure NCF.

18. The method of claim 16, wherein positioning the NCF over the CoW arrangement includes laminating the NCF over the CoW arrangement on an end of the CoW arrangement opposite the substrate.

19. The method of claim 18, wherein the laminating the NCF over the CoW arrangement is performed prior to inserting the substrate with the CoW arrangement thereon into the chamber of the mold.

20. The method of claim 16, wherein the NCF comprises one or more of materials chosen from among a polymer and a flux.
